(19) United States
(12) Patent Application Publication
(10) Pub. No.: US 2025/0293510 A1
(43) Pub. Date: Sep. 18, 2025

(54) POWER SUPPLY CIRCUIT

(71) Applicant: DENSO CORPORATION, Kariya-city (JP)

(72) Inventor: Masahiko ITO, Kariya-city (JP)

(73) Assignee: DENSO CORPORATION, Kariya-city (JP)

(21) Appl. No.: 19/226,959

(22) Filed: Jun. 3, 2025

Related U.S. Application Data
(63) Continuation of application No. PCT/JP2023/041066, filed on Nov. 15, 2023.

(30) Foreign Application Priority Data
Dec. 7, 2022 (JP) 2022-195420

(51) Int. Cl. H02H 7/18; G01R 31/374; G01R 31/3842; G01R 31/396; H01M 10/42

(52) U.S. Cl. CPC H02H 7/18; G01R 31/374; G01R 31/3842; G01R 31/396; H01M 10/425; H01M 2010/4271

(57) ABSTRACT

A power supply circuit is supplied power from a battery and supply power to a battery monitoring unit that monitors the condition of the battery. The power supply circuit includes: a fuse function unit, provided in a current path connecting the battery and the battery monitoring unit, that interrupts a current exceeding a predetermined current, a path resistor provided in the current path between the fuse function unit and the battery monitoring unit, and a formation circuit that forms a bypass path that allows the current exceeding the predetermined current to flow to the fuse function unit without passing through the path resistor when a short circuit occurs in a path through the path resistor.

### CROSS-REFERENCE TO RELATED APPLICATIONS

The present application is a continuation application of International Application No. PCT/JP2023/041066 filed on Nov. 15, 2023, which claims priority to Japanese Application No. 2022-195420 filed on Dec. 7, 2022. The contents of these applications are incorporated herein by reference in their entirety.

### BACKGROUND

### 1. Technical Field

This disclosure relates to a power supply circuit as applied to a battery monitoring device.

### 2. Related Art

“TEXAS INSTRUMENTS BQ79616-Q1 DATASHEET REV. D” discloses a battery monitoring device including a power supply circuit that receives power from a battery and a battery monitoring IC that operates by the power supplied from the power supply circuit and monitors the battery status.

### SUMMARY

In a battery monitoring device as described above, a fuse is generally provided in the current path from the battery to the battery monitoring IC, and when a short circuit occurs in the power supply circuit the fuse blows to interrupt the current. However, when the battery voltage is low or the resistance value of the path resistor in the current path is high, the fuse may not blow even if a short circuit occurs. In this case, discharge from the battery may continue while a short circuit occurs, causing the battery to over-discharge or the battery to overheat. The same problem can occur not only with metal fuses that blow due to overcurrent, but also with fuse function units including resettable fuses whose resistance value increases due to overcurrent, e-fuses (electronic fuses) that detect overcurrent and interrupt the current using a MOSFET, and others.

This disclosure aims to provide a power supply circuit that can interrupt the discharge current from the battery when a short circuit occurs in a power supply circuit with a path resistor in the current path, even when the voltage of the input source battery is low or the resistance value of the path resistor is high.

One aspect of this disclosure is a power supply circuit receiving power from a battery and supplying power to a battery monitoring unit that monitors the condition of the battery. The power supply circuit includes: a fuse function unit, provided in a current path connecting the battery and the battery monitoring unit, that interrupts a current exceeding a predetermined current, a path resistor provided in the current path between the fuse function unit and the battery monitoring unit, and a formation circuit that forms a bypass path that allows the current exceeding the predetermined current to flow to the fuse function unit without passing through the path resistor when a short circuit occurs in a path through the path resistor.

Another aspect of this disclosure is a power supply circuit receiving power from a battery and supplying power to a battery monitoring unit that monitors the condition of the battery. The power supply circuit includes: a first fuse function unit, provided in a current path connecting the battery and the battery monitoring unit, that interrupts a current exceeding a predetermined current, a path resistor provided in the current path between the first fuse function unit and the battery monitoring unit, and an interruption circuit that interrupts the current flowing through the path resistor when a short circuit occurs in the path through the path resistor.

### BRIEF DESCRIPTION OF THE DRAWING

The above and other objects, features and advantages of the present disclosure will become clearer with the following detailed description with reference to the accompanying drawings. The drawings are:

FIG. 1 shows a block diagram of a battery monitoring device;

FIG. 2 shows a circuit diagram of a power supply circuit and a battery monitoring IC according to a first embodiment;

FIG. 3 shows a modification of a circuit diagram of a power supply circuit and a battery monitoring IC according to the first embodiment;

FIG. 4 shows a circuit diagram of a power supply circuit and a battery monitoring IC according to a second embodiment;

FIG. 5 shows a circuit diagram of a power supply circuit and a battery monitoring IC according to a third embodiment;

FIG. 6 shows a circuit diagram of a power supply circuit and a battery monitoring IC according to a fourth embodiment;

FIG. 7 shows a modification of a circuit diagram of a power supply circuit and a battery monitoring IC according to the fourth embodiment;

FIG. 8 shows a circuit diagram of a power supply circuit and a battery monitoring IC according to a fifth embodiment;

FIG. 9 shows a modification of a circuit diagram of the power supply circuit and battery monitoring IC modifications of the fifth embodiment;

FIG. 10 shows a circuit diagram of a power supply circuit and a battery monitoring IC according to a sixth embodiment;

FIG. 11 shows a circuit diagram of a power supply circuit and a battery monitoring IC according to a seventh embodiment;

FIG. 12 shows a circuit diagram of a power supply circuit and a battery monitoring IC according to an eighth embodiment;

FIG. 13 shows a modification of a circuit diagram of a power supply circuit and a battery monitoring IC according to the eight embodiment;

FIG. 14 shows a circuit diagram of a power supply circuit and a battery monitoring IC according to a ninth embodiment.

### DETAILED DESCRIPTION OF THE PREFERRED EMBODIMENTS

The first aspect to solve the above problem is a power supply circuit receiving power from a battery and supplying power to a battery monitoring unit that monitors the condition of the battery. The power supply circuit includes: a fuse function unit, provided in a current path connecting the battery and the battery monitoring unit, that interrupts a current exceeding a predetermined current, a path resistor provided in the current path between the fuse function unit and the battery monitoring unit, and a formation circuit that forms a bypass path that allows the current exceeding the predetermined current to flow to fuse function unit without passing through the path resistor when a short circuit occurs in a path through the path resistor.

According to the above configuration, the power supply circuit is supplied power from the battery and supplies power to the battery monitoring unit that monitors the condition of the battery. The power supply circuit includes a fuse function unit, provided in a current path connecting the battery and the battery monitoring unit, that interrupts a current exceeding a predetermined current. Therefore, when a short circuit occurs in power supply circuit and a current exceeding the predetermined current flows to the fuse function unit, the current is interrupted by the fuse function unit. The fuse function unit may be a metal fuse that melts due to overcurrent, a resettable fuse whose resistance value increases due to overcurrent, or an e-fuse (electronic fuse) that detects the overcurrent and interrupts the current using a MOSFET.

A typical power supply circuit includes a path resistor between the fuse function unit and the battery monitoring unit in the current path. Therefore, when the battery voltage is low or the resistance value of the path resistor is high, even if a short circuit occurs, the current flowing through the fuse function unit may not exceed the predetermined current and the fuse function unit may not work. In this regard, the formation circuit of the first aspect forms a bypass path that allows current exceeding the predetermined current to flow to the fuse function unit without passing through the path resistor when a short circuit occurs in the path through the path resistor. Thus, even if the current flowing to the fuse function unit through the path resistor does not exceed the predetermined current when a short circuit occurs, the current flowing to the fuse function unit through the bypass path can exceed the predetermined current. Therefore, even if the voltage of the battery, which is input source, is low or the resistance value of the path resistor is high, the fuse function unit interrupts the discharge current from the battery when a short circuit occurs.

The second aspect is the power supply circuit wherein the formation circuit comprises a first conduction element, and the first conduction element is connected to the current path in parallel with the path resistor, and when a voltage exceeding a first predetermined voltage is applied, energizes and causes a current exceeding the predetermined current to flow to the fuse function unit. According to such a configuration, when a short circuit occurs in power supply circuit and a voltage exceeding the first predetermined voltage is applied to the first conduction element, the first conduction element connected to the current path in parallel with the path resistor energizes to form a bypass path, and a current exceeding the predetermined current flows to the fuse function unit. Therefore, a simple configuration of the formation circuit can interrupt the discharge current from the battery when a short circuit occurs. The first conduction element energizes when a voltage exceeding the first predetermined voltage is applied may be a Zener diode, TVS diode, varistor, etc.

The third aspect is the power supply circuit further including a switching element whose open/close state is controlled by the battery monitoring unit, connected in the current path between the path resistor and the first conduction element, and the battery monitoring unit, wherein the formation circuit includes a second conduction element, and the second conduction element is connected in parallel with the battery monitoring unit between the switching element and the battery monitoring unit and energizes when a voltage exceeding a second predetermined voltage, which is lower than the first predetermined voltage, is applied.

According to the above configuration, the switching element is provided between the path resistor and the first conduction element, and the battery monitoring unit in the current path, and its open/close state is controlled by the battery monitoring unit. Therefore, when the switching element is in a normal state, the current flowing to the battery monitoring unit and the voltage applied to the battery monitoring unit are appropriately regulated. On the other hand, when the switching element is short circuited, the current flowing to the battery monitoring unit cannot be interrupted and if the fuse function unit does not work when the battery voltage is low or the resistance value of the path resistor is high, the discharge from the battery may continue due to a short circuit.

In this regard, the second conduction element is connected in parallel with the battery monitoring unit between the switching element and the battery monitoring unit and energizes when a voltage exceeding the second predetermined voltage, which is lower than the first predetermined voltage, is applied. Therefore, the second conduction element connected in parallel with the battery monitoring unit energizes when a voltage exceeding the second predetermined voltage is applied to the second conduction element due to a short circuit of the switching element. As a result, a voltage exceeding the first predetermined voltage is applied to the first conduction element, the first conduction element is energized, and a bypass path through the first and second conduction elements is formed. Therefore, a current exceeding the predetermined current can flow through the fuse function unit, and the discharge current from the battery is interrupted when a short circuit occurs in the switching element. The same effect can be achieved when the second conduction element connected in parallel to the current path is not in the power supply circuit but in the battery monitoring unit.

When the battery monitoring part includes a switching element connected in series with the current path from the battery to the battery monitoring part, the battery monitoring part generally includes a protective element similar to the second conduction element of the third aspect, in case the switching element is short circuited. Therefore, when the fourth aspect is that the switching element is provided in the current path, the same effect as in the third aspect can be achieved.

The fifth aspect is the power supply circuit including a plurality of the current paths, wherein a plurality of the path resistors is provided in the plurality of the current paths respectively, and the formation circuit includes a plurality of the first conduction elements provided in the plurality of the current paths respectively. According to such a configuration, even if a short circuit occurs in any of the plurality of current paths, the discharge current from the battery is interrupted in the event of a short circuit, as in the second aspect.

The sixth aspect is the power supply circuit wherein the formation circuit includes a noise reduction element that reduces noise applied to the first conduction element and has a lower resistance value than the path resistor. According to such a configuration, it is possible to suppress the current flowing in the fuse function unit from being reduced by the noise reducing element while suppressing the first conduction element from malfunctioning or being damaged by noise.

The seventh aspect is the power supply circuit wherein the formation circuit includes: a switch connected in parallel with the battery in the current path between the fuse function unit and the path resistor, and a switch drive unit that closes the switch when a current exceeding the first current, which is smaller than the predetermined current, flows through the path resistor. According to such a configuration, when a short circuit occurs in the power supply circuit and a current exceeding the first current flows through the path resistor, the switch connected in parallel with the battery between the fuse function unit of the current path and the path resistor closes to form a bypass path, allowing a current exceeding the predetermined current to flow through the fuse function unit. Thus, the discharge current from the battery is interrupted in the event of a short circuit.

The eighth aspect is the power supply circuit according to the seventh aspect further including a switching element whose open/close state is controlled by the battery monitoring unit is connected in the current path between the path resistor and the battery monitoring unit, wherein the formation circuit comprises a second conduction element, and the second conduction element is connected in parallel with the battery monitoring unit in the current path between the switching element and the battery monitoring unit and energizes when a voltage exceeding the second predetermined voltage is applied.

According to the above configuration, when the switching element is short circuited, the current flowing to the battery monitoring unit is not interrupted and if the fuse function unit does not work when the battery voltage is low or the resistance value of the path resistor is high, the discharge from the battery may continue with a short circuit.

In this regard, the second conduction element is connected in parallel with the battery monitoring unit between the switching element and the battery monitoring unit and energizes when a voltage exceeding the second predetermined voltage is applied. Therefore, when the switching element is short circuited and a voltage exceeding the second predetermined voltage is applied to the second conduction element, the second conduction element energizes. As a result, a current exceeding the first current flows in the path resistor and the switch closes, forming a bypass path through the fuse function unit and the switch. Therefore, a current exceeding the predetermined current can flow in the fuse function unit and the discharge current from the battery is interrupted when a short circuit occurs in the switching element.

The ninth aspect is the power supply circuit including a plurality of the current paths, wherein a plurality of the path resistors is provided in the plurality of the current paths respectively, and the formation circuit includes a plurality of the switch drive unit provided in the plurality of the current paths respectively. According to this configuration, even if a short circuit occurs in any of the plurality of current paths, the discharge current from the battery is interrupted in the same manner as in the seventh aspect.

The tenth aspect is a power supply circuit receiving power from a battery and supplying power to a battery monitoring unit that monitors the condition of the battery. The power supply circuit includes: a first fuse function unit, provided in a current path connecting the battery and the battery monitoring unit, that interrupts a current exceeding a predetermined current, a path resistor provided in the current path between the first fuse function unit and the battery monitoring unit, and an interruption circuit that interrupts the current flowing through the path resistor when a short circuit occurs in the path through the path resistor.

According to the above configuration, the power supply circuit is supplied power from the battery and supplies power to the battery monitoring unit that monitors the condition of the battery. A first fuse function unit is provided in a current path connecting the battery and the battery monitoring unit, that interrupts a current exceeding a predetermined current. Therefore, when a short circuit occurs in the power supply circuit and a current exceeding the predetermined current flows in the fuse function unit, the current is interrupted by the fuse function unit.

Here, the power supply circuit includes a path resistor between the first fuse function unit and the battery monitoring unit in the current path. Therefore, when the battery voltage is low or the resistance value of the path resistor is high, even if a short circuit occurs, the current flowing to the first fuse function unit may not exceed the predetermined current, and the first fuse function unit may not work. In this regard, the interruption circuit interrupts the current flowing through the path resistor when a short circuit occurs in the path through the path resistor. Therefore, even if the current flowing through the path resistor to the first fuse function unit does not exceed the predetermined current when a short circuit occurs, the current flowing through the path resistor is interrupted. Therefore, even if the voltage of the input source battery is low or the resistance value of the path resistor is high, the discharge current from the battery is interrupted when a short circuit occurs.

The eleventh aspect is the power supply circuit wherein the interruption circuit comprises: a switch connected in series with the first fuse function unit and the path resistor in the current path, and a switch drive unit that opens the switch when a current exceeding the first current, which is smaller than the predetermined current, flows through the path resistor. According to such a configuration, when a short circuit occurs in the power supply circuit and a current exceeding the first current flows in the path resistor, the switch connected in series with the first fuse function unit and the path resistor opens in the current path. Therefore, even if the voltage of the input source battery is low or the resistance value of the path resistor is high, the discharge current from the battery is interrupted when a short circuit occurs.

The twelfth aspect is the power supply circuit wherein the interruption circuit includes a second fuse function unit, and the second fuse function unit is connected in series with a predetermined element, the predetermined element being connected in parallel with the current path, and when a short circuit does not occur in the predetermined element a current exceeding a first current that is smaller than the predetermined current does not flow, and a current exceeding the first current flows, interrupting the current flowing through the path resistor.

According to the above configuration, the second fuse function unit is connected in series with a predetermined element connected in parallel with the current path, and when a short circuit does not occur at the predetermined element, current exceeding the first current, which is smaller than the predetermined current, does not flow, and when a current exceeding the first current flows, the current is interrupted. Therefore, when a short circuit does not occur in a predetermined element, the second fuse function unit does not interrupt the current and allows the current to flow to the predetermined element. On the other hand, the second fuse function unit interrupts the current when the current exceeds the first current. Therefore, when a short circuit occurs in a predetermined element, even if the current flowing to the first fuse function unit does not exceed the predetermined current and the first fuse function unit does not work, the current is interrupted by the second fuse function unit when a current exceeding the first current, which is smaller than the predetermined current, flows to the second fuse function unit. Therefore, even if the voltage of the battery of the input source is low or the resistance value of the path resistor is high, the discharge current from the battery is interrupted when the predetermined element is short circuited.

### First Embodiment

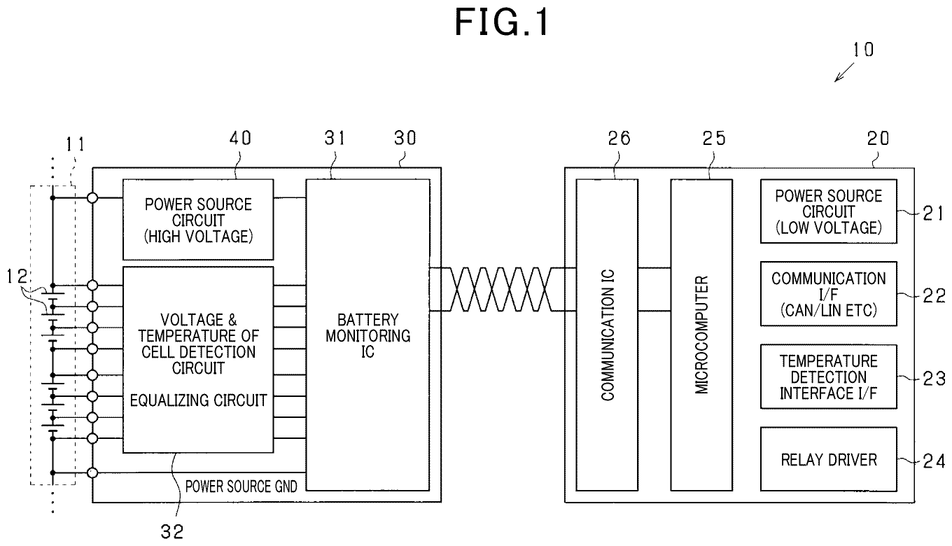

The following is a description of the first embodiment embodied in the power supply circuit as applied to a battery monitoring device installed in a vehicle etc., with reference to the drawings. As shown in FIG. 1, a battery monitoring device 10 includes a main device 20 and a sub device 30.

The main device 20 includes a power supply circuit 21, a communication interface (I/F) 22, a temperature detection interface (I/F) 23, a relay driver 24, a microcomputer 25, a communication IC 26, etc. The main device 20 communicates with the sub device 30, which monitors the state of each cell 12 of a battery 11 and the battery 11. The battery 11 may include, for example, a plurality of cells 12 connected in series or in parallel.

The sub device 30 includes a battery monitoring IC 31, a detection circuit 32, a power supply circuit 40, etc. The power supply circuit 40 receives power from the battery 11 and supplies power to the battery monitoring IC. The battery monitoring IC (an example of “battery monitoring unit”) operates by the power supplied by the power supply circuit 40. The detection circuit 32 detects the status of each cell 12 and the battery 11. The detection circuit 32 is controlled by the battery monitoring IC and detects the voltage of the cell 12, detects the temperature of the cell 12, and equalizes the voltage of the cell 12. The detection circuit 32 may also detect the current flowing in the cell 12 or the battery 11, detect the internal pressure of the cell 12, detect gas leakage from the cell 12, etc.

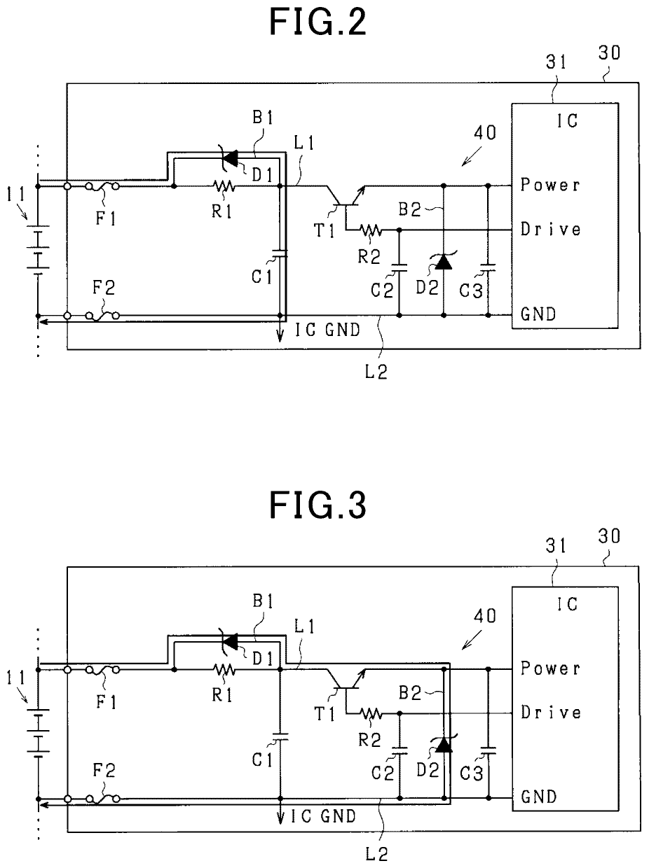

FIG. 2 shows the circuit diagram of the power supply circuit 40 and the battery monitoring IC 31. A fuse F1, a resistor R1, and a transistor T1 are connected in series in this order on a wiring L1 (current path). The wiring L1 connects a positive terminal of the battery 11 and a power input (power) of the battery monitoring IC 31. A fuse F2 is provided on a wiring L2 (current path). The wiring L2 connects a GND terminal of the battery monitoring IC and a negative terminal of the battery 11.

Each fuse F1, F2 (an example of fuse function unit) may be, for example, a metal fuse that blows and interrupts the current when a current exceeding 0.5 to 1.0 [A] (predetermined current If) flows. The metal fuses are not limited to those with fuse elements made of metal with a low melting point in wire form but may also be pattern fuses in which the pattern width of the wiring is thinner than the rest of the wiring to blow due to overcurrent.

In the wiring L1, between the resistor R1 and the transistor T1, a capacitor C1 is connected in parallel with the battery 11 and the battery monitoring IC 31. The resistor R1 and capacitor C1 constitute an RC filter (low-pass filter) that reduces noise applied to the transistor T1. The resistance value of the resistor R1 (path resistor) is set according to the assumed noise frequency. For example, the resistance value of the resistor R1 may be 100 to several thousand [Ω]. The resistor R1 may include multiple resistors.

In the wiring L1, between the transistor T1 and the power input terminal of the battery monitoring IC, a capacitor C3 is connected in parallel with the battery 11 and the battery monitoring IC 31. The base of the transistor T1 (switching element) is connected to a drive terminal (drive) of the battery monitoring IC via an RC filter configured by the resistor R2 and capacitor C2. The transistor T1 is not limited to a bipolar transistor but may be a unipolar transistor such as a MOSFET.

The battery monitoring IC 31 controls the open/close period or open/close degree of the transistor T1, i.e., open/close state, based on the output of the drive terminal. The battery monitoring IC 31 controls the charge stored in capacitor C3 by controlling the open/close state of the transistor T1, so that the voltage input to the power input of battery monitoring IC approaches a target voltage.

Suppose that a Zener diode D1 is not connected to the wiring L1 in parallel with the resistor R1 and the capacitor C1 is short circuited. In this case, depending on the resistance value of resistor R1, the current flowing through fuse F1, the resistor R1, the capacitor C1, and the fuse F2 in this order may decrease to tens to hundreds [mA]. In this case, the current flowing through the fuse F1 and the fuse F2 may not exceed the predetermined current If, and the fuse F1 and the fuse F2 may not blow. As a result, discharge from the battery 11 may continue with a short circuit, resulting in over discharge of the battery 11 or overheating of the battery 11.

Therefore, in this embodiment, the Zener diode D1 (first conduction element) is connected to the wiring L1 in parallel with the resistor R1. The wiring B1 connects the anode of the Zener diode D1 to a portion between the resistor R1 and the transistor T1, and the cathode of the Zener diode D1 to a portion between the resistor R1 and the fuse F1. The Zener diode D1 yields when a voltage exceeding the first predetermined voltage V1, which is lower than the lowest voltage in the range of use (range of variation) of the battery 11, is applied, forming a Zener voltage (a constant voltage). The resistance value of the Zener diode D1 in the yield state is, for example, a few [Ω]. The Zener diode D1 and the wiring B1 connecting the Zener diode D1 to the wiring L1 constitute a formation circuit.

When the capacitor C1 is short circuited, the voltage applied to the Zener diode D1 exceeds the first predetermined voltage V1, and the Zener diode D1 yields (energizes). As a result, the current flows through the fuse F1, the Zener diode D1, the capacitor C1, and fuse the F2 in this order, bypassing the resistor R1. Since the resistance value of the Zener diode D1 in the yielded state is sufficiently lower than that of the resistor R1, the current exceeding the predetermined current If flows through the fuse F1 and the F2 even if the voltage of the battery 11 is the lowest voltage in the range of use. Thus, the Zener diode D1 energizes when a voltage exceeding the first predetermined voltage V1 is applied, and the current exceeding the predetermined current If flows to the fuse F1 and the F2. As a result, at least one of the fuse F1 and the fuse F2 blows and the current is interrupted.

Suppose that in FIG. 3, there is no Zener diode D2 connected between transistor T1 and battery monitoring IC 31 in parallel with battery monitoring IC in wiring L1, and that transistor T1 is short circuited. In this case, the current flowing in the power input of the battery monitoring IC 31 cannot be interrupted. Furthermore, if neither the fuse F1 nor the fuse F2 work when the voltage of the battery 11 is low or the resistance value of the resistor R1 is high, discharge from battery 11 may continue with a short circuit.

Therefore, in this embodiment, the Zener diode D2 is provided between the transistor T1 and the battery monitoring IC 31 in the wiring L1, in parallel with the battery monitoring IC. The wiring B1 connects the anode of the Zener diode D2 to the wiring L2 and the cathode of the Zener diode D1 to the wiring L1. The Zener diode D2 yields when a voltage exceeds the second predetermined voltage V2, which is lower than the first predetermined voltage V1, is applied, forming a Zener voltage (constant voltage). When the transistor T1 is not short circuited and the open/close state of the transistor T1 is controlled, the voltage applied to the Zener diode D2 is lower than the second predetermined voltage V2. The resistance value of the Zener diode D2 in the yielded state is, for example, a few [Ω]. The Zener diode D1, the wiring B1 connecting the Zener diode D1 to the wiring L1, and the Zener diode D2 and the wiring B1 connecting the Zener diode D2 to the wiring L1 and L2 constitute a formation circuit.

When transistor T1 is short circuited, the voltage applied to the Zener diode D2 exceeds the second predetermined voltage V2, and the Zener diode D2 yields. Next, the voltage applied to the Zener diode D1 exceeds the first predetermined voltage V1, and the Zener diode D1 yields. As a result, the current bypasses the resistor R1 and flows through the fuse F1, the Zener diode D1, the transistor T1, the Zener diode D2, and the fuse F2 in that order. At this time, the resistance values of the Zener diode D1 and the Zener diode D2 in the yielded state are sufficiently lower than that of the resistor R1, so that a current exceeding the predetermined current If flows through the fuse F1 and the fuse F2 even if the battery 11 voltage is the lowest voltage in the operating range. As a result, at least one of the fuse F1 and the fuse F2 will blow, interrupting the current.

This embodiment, detailed above, has the following advantages.

The Zener diode D1 and the wiring B1 form a bypass path that allows the current exceeding the predetermined current If to flow to the fuse F1 and the fuse F2 without passing through the resistor R1 when a short circuit occurs in the path passing through the resistor R1. Therefore, when a short circuit occurs in the path through resistor R1, even if the current flows through the resistor R1 to the fuses F1 and the fuse F2 does not exceed the predetermined current If, the current flowing through the bypass path to the fuses F1 and the fuse F2 exceeds the predetermined current If. Therefore, even when the voltage of the input source battery 11 is low or the resistance value of the resistor R1 is high, the fuse F1 and the fuse F2 can work when a short circuit occurs in the path through resistor R1, and the discharge current from the battery 11 is interrupted.

When a short circuit occurs in the power supply circuit 40 and a voltage exceeding the first predetermined voltage V1 is applied to the Zener diode D1, the Zener diode D1 connected to the wiring L1 in parallel with the resistor R1 is energized to form the bypass path, allowing the current exceeding the predetermined current If to flow through the fuse F1 and the fuse F2. Therefore, the discharge current from the battery 11 is interrupted in the event of a short circuit by the concisely configured formation circuit.

The Zener diode D2 is connected in parallel with the battery monitoring IC 31 between the transistor T1 and the battery monitoring IC 31 in the wiring L1 and is energized when a voltage exceeding the second predetermined voltage V2, which is lower than the first predetermined voltage V1, is applied. Therefore, when the transistor T1 is short circuited and a voltage exceeding the second predetermined voltage V2 is applied to the Zener diode D2, the Zener diode D2 connected in parallel with the battery monitoring IC 31 is energized. As a result, a voltage exceeding the first predetermined voltage V1 is applied to the Zener diode D1, which energizes the Zener diode D1 and forms a bypass path through the Zener diode D1 and the Zener diode D2. This allows a current exceeding the predetermined current If to flow through the fuse F1 and the fuse F2, thus interrupting the discharge current from the battery 11 when a short circuit occurs in the transistor T1.

The same effect can be achieved not only when the capacitor C1 is short circuited, but also when the portion between the resistor R1 and the transistor T1 in the wiring L1 and the wiring L2 are directly short circuited.

The same effect can also be achieved when the Zener diode D2 connected in parallel to the wiring L1 is built into (provided in) the battery monitoring IC 31 instead of the power supply circuit 40.

### Second Embodiment

The following is a description of the second embodiment with reference to the drawings, focusing on the differences from the first embodiment. The same parts as those of the first embodiment will be omitted from the explanation by applying the same symbols.

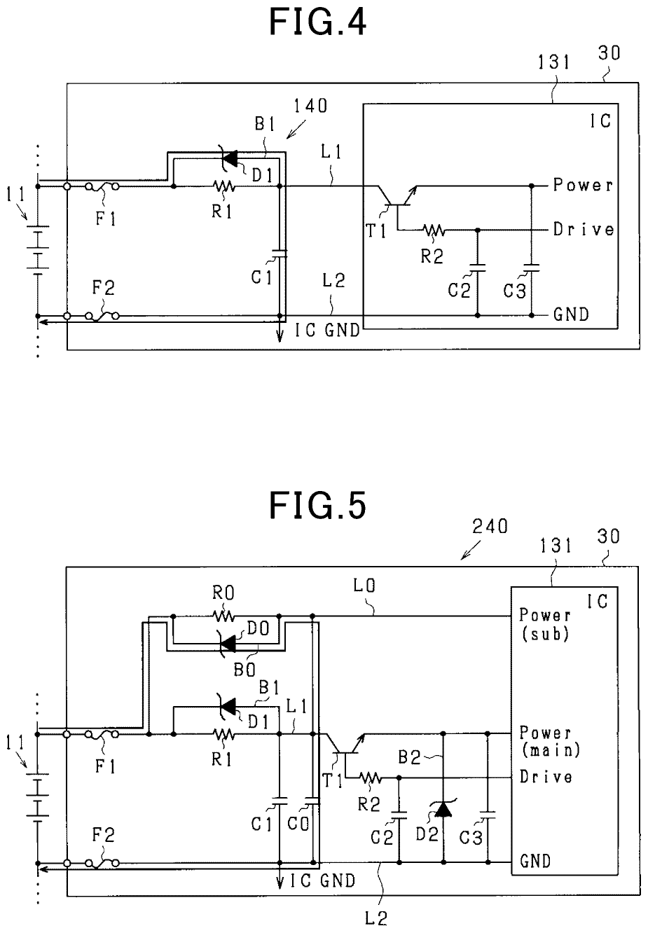

As shown in FIG. 4, the battery monitoring IC 131 incorporates (includes) the transistor T1, the resistor R2, and the capacitors C2 and C3, whose open/close state is controlled. The transistor T1 is provided in the wiring L1. The power supply circuit 140 has the Zener diode D1 and does not include the transistor T1, the resistor R2 and the capacitors C2 and C3.

When the battery monitoring IC 31 incorporates the transistor T1 provided in the wiring L1 connecting the battery 11 and the battery monitoring IC 131, the battery monitoring IC 131 generally includes a protective element (not shown) like the above Zener diode D2 in case the transistor T1 is short circuited. Therefore, this embodiment can have the same effect as the first embodiment.

### Third Embodiment

The following is a description of the third embodiment with reference to the drawings, focusing on the differences from the first embodiment. The same parts as those of the first embodiment will be omitted from the explanation by applying the same symbols.

As shown in FIG. 5, the power supply circuit 240 includes the wiring L1 (current path) connecting the positive terminal of battery 11 and the main power input (power (main)) of the battery monitoring IC 31 and the wiring L0 (current path) connecting the positive terminal of the battery 11 and the sub power input (power (sub)) of the battery monitoring IC 31.

A resistor R0 (path resistor) is provided in the wiring L2. In the wiring L0, a capacitor C0 is connected in parallel with the battery 11 and the battery monitoring IC 31 between the resistor R0 and the sub power input of the battery monitoring IC. A Zener diode DO (first conduction element) like the Zener diode D1 is connected in parallel with the resistor R0 in the wiring L0. The wiring B0 connects the anode of Zener diode DO to a portion between the resistor R1 and the battery monitoring IC 31, and the cathode of Zener diode D0 to a portion between the resistor R1 and the fuse F1. In other words, in this embodiment, the formation circuit is present for each of the wires L1 and L0 (multiple wires) and includes the Zener diode D1 and the wiring B1 corresponding to the wire L1 and the Zener diode D0 and the wiring B0 corresponding to the wire L0.

According to the above configuration, even if a short circuit occurs in either the wiring L1 or the wiring L0, the discharge current from the battery 11 is interrupted when a short circuit occurs, like the first embodiment. For example, when the capacitor C0 (the wiring L0) is short circuited, the voltage applied to the Zener diode D0 exceeds the first predetermined voltage V1, causing the Zener diode D0 to yield (energize). As a result, the current bypasses the resistor R0 and flows to the fuse F1, the Zener diode D0, the capacitor C0, and the fuse F2, in this order. As a result, at least one of the fuse F1 and the fuse F2 blows, interrupting the current.

### Fourth Embodiment

The following is a description of the fourth embodiment with reference to the drawings, focusing on the differences from the first embodiment. The same parts as those of the first embodiment will be omitted from the explanation by applying the same symbols.

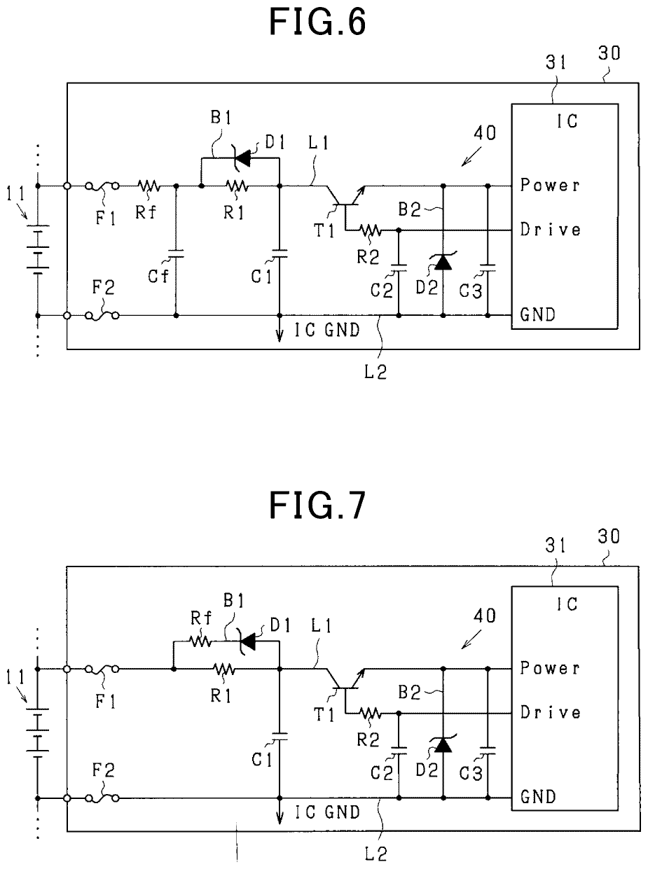

As shown in FIG. 6, the power supply circuit 40 includes a resistor Rf, which reduces noise applied to the Zener diode D1 and has a lower resistance value than the resistor R1, and a capacitor Cf. In the wiring L1, between the resistor Rf and the resistor R1, the capacitor Cf is connected in parallel with the battery 11 and the battery monitoring IC 31. The resistor Rf and the capacitor Cf constitute an RC filter (low-pass filter) that reduces noise applied to the Zener diode D1. The resistance value of resistor Rf may be, for example, several [Ω], and is set to a resistance value that causes the fuse F1 and the fuse F2 to blow when the capacitor C1 is short circuited. The resistor Rf may be composed of multiple resistors.

According to the above configuration, the malfunction or failure of the Zener diode D1 due to noise is suppressed and the decrease of the current flowing to the fuse F1 and the fuse F2 due to the resistor Rf is suppressed. Therefore, even when the voltage of the battery 11, which is input source, is low or the resistance value of the resistor R1 is high, the fuse F1 and the fuse F2 can work when a short circuit occurs, and the discharge current from the battery 11 is interrupted.

As shown in FIG. 7, instead of the resistor Rf and capacitor Cf of FIG. 6, the power supply circuit 40 may have the resistor Rf connected in series with the Zener diode D1 in the wiring B1. The resistor Rf reduces noise applied to the Zener diode D1 and has a lower resistance value than the resistor R1. The resistance value of the resistor R1 may be, for example, several [Ω], and is set to a resistance value that causes the fuse F1 and the fuse F2 to blow when the capacitor C1 is short circuited. The resistor Rf may be composed of multiple resistors.

This configuration also prevents the current flowing to the fuse F1 and the fuse F2 from being reduced by the resistor Rf, while preventing the Zener diode D1 from malfunctioning or being damaged by noise. Therefore, even when the voltage of the battery 11, which is input source, is low or the resistance value of the resistor R1 is high, the fuse F1 and the fuse F2 can work when a short circuit occurs, and the discharge current from the battery 11 is interrupted.

### Fifth Embodiment

The following is a description of the fifth embodiment with reference to the drawings, focusing on the differences from the first embodiment. The same parts as those of the first embodiment will be omitted from the explanation by applying the same symbols.

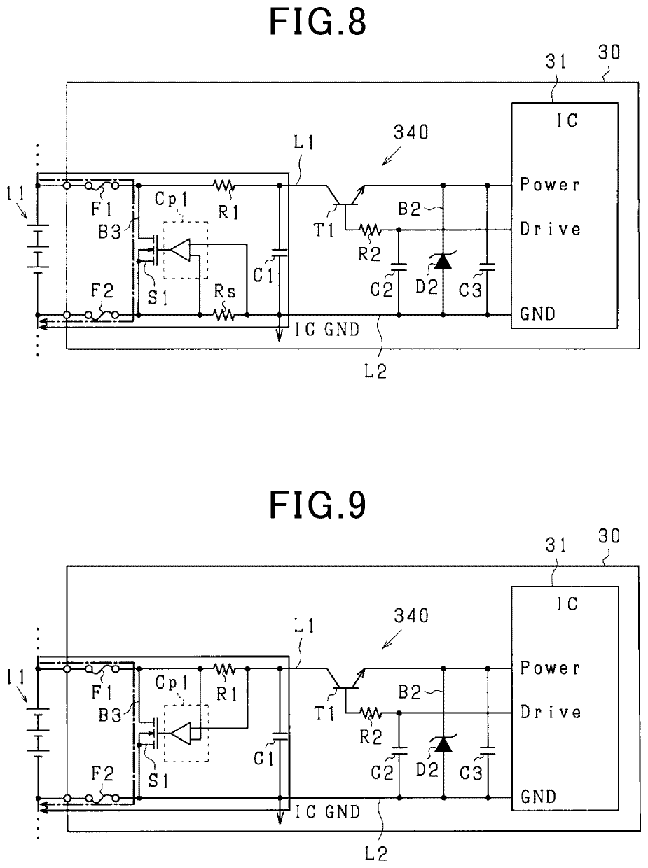

As shown in FIG. 8, the power supply circuit 40 includes a switch S1 in the wiring B3 connected in parallel with battery 11 between the fuse F1 in the wiring L1 and the resistor R1, and a comparator Cp1 that drives the switch S1. The switch S1 may be, for example, an n-Channel MOSFET. A shunt resistor Rs is provided between the capacitor C1 and the battery 11 in the wiring L2. The gate of the switch S1 is connected to the output of comparator Cp1, the drain of the switch S1 is connected to the connection point of the fuse F1 and the resistor R1, and the source of the switch S1 is connected to the connection point of the fuse F2 and the shunt resistor Rs. The comparator Cp1 turns on (closes) the switch S1 when the voltage at both ends of the shunt resistor Rs exceeds a threshold value. The threshold value is set to a voltage lower than the voltage applied to the shunt resistor Rs when capacitor C1 is short circuited and a predetermined current If flows through the shunt resistor Rs, which causes the fuse F1 to blow. In other words, the comparator Cp1 closes the switch S1 when a current exceeding the first current I1, which is smaller than the predetermined current If, flows through the resistor R1. The first current I1 is a current smaller than the current flowing through the resistor R1 when the capacitor C1 is short circuited, when the voltage of the battery 11 is the lowest voltage in the range of use (range of variation) or when the resistance value of the resistor R1 is high. When the capacitor C1 is not short circuited, the current flowing through the resistor R1 is smaller than the current I1. The comparator Cp1 and the shunt resistor Rs constitute the switch drive unit. The switch S1, the wiring B3, the comparator Cp1, and the shunt resistor Rs constitute the formation circuit. An operational amplifier may be provided instead of the comparator Cp1.

According to the above configuration, when capacitor C1 is short circuited and the current exceeding the first current I1 flows through the resistor R1, the switch S1 connected in parallel with the battery 11 between the fuse F1 of the wiring L1 and the resistor R1 is closed and a bypass path is formed, allowing the current exceeding the predetermined current If to flow through the fuse F1 and the fuse F2 can flow through the fuse F1 and the fuse F2. Therefore, the discharge current from the battery 11 is interrupted when a short circuit occurs.

The Zener diode D2 (second conduction element) is connected in parallel with the battery monitoring IC 31 between the transistor T1 and the battery monitoring IC 31 in the wiring L1. The Zener diode D2 energizes when a voltage exceeding the second predetermined voltage V2 is applied. Therefore, when the transistor T1 is short circuited and a voltage exceeding the second predetermined voltage V2 is applied to the Zener diode D2, the Zener diode D2 energizes. As a result, a current exceeding the first current I1 flows in the resistor R1 and the switch S1 is closed, forming a bypass path through the fuse F1, the switch S1, and the fuse F2. Therefore, a current exceeding the predetermined current If can flow through the fuse F1 and the F2, and the discharge current from the battery 11 is interrupted when transistor T1 is short circuited.

As shown in FIG. 9, the comparator Cp1 may turn on (close) the switch S1 when the voltage on both ends of the resistor R1 exceeds the threshold value. The threshold value is set to a voltage lower than the voltage applied to the resistor R1 when capacitor C1 is short circuited and the predetermined current If flows through the resistor R1, which causes the fuse F1 to blow. In other words, the comparator Cp1 closes the switch S1 when a current exceeding the first current I1, which is smaller than the predetermined current If, flows through the resistor R1. When the capacitor C1 is not short circuited, the current flowing through the resistor R1 is smaller than the first current I1. The comparator Cp1 and the resistor R1 constitute the switch drive unit. The switch S1, the wiring B3, the comparator Cp1, and the resistor R1 constitute the formation circuit. An operational amplifier may be provided instead of the comparator Cp1.

### Sixth Embodiment

The following is a description of the sixth embodiment with reference to the drawings, focusing on the differences from the first embodiment. The same parts as those of the first embodiment will be omitted from the explanation by applying the same symbols.

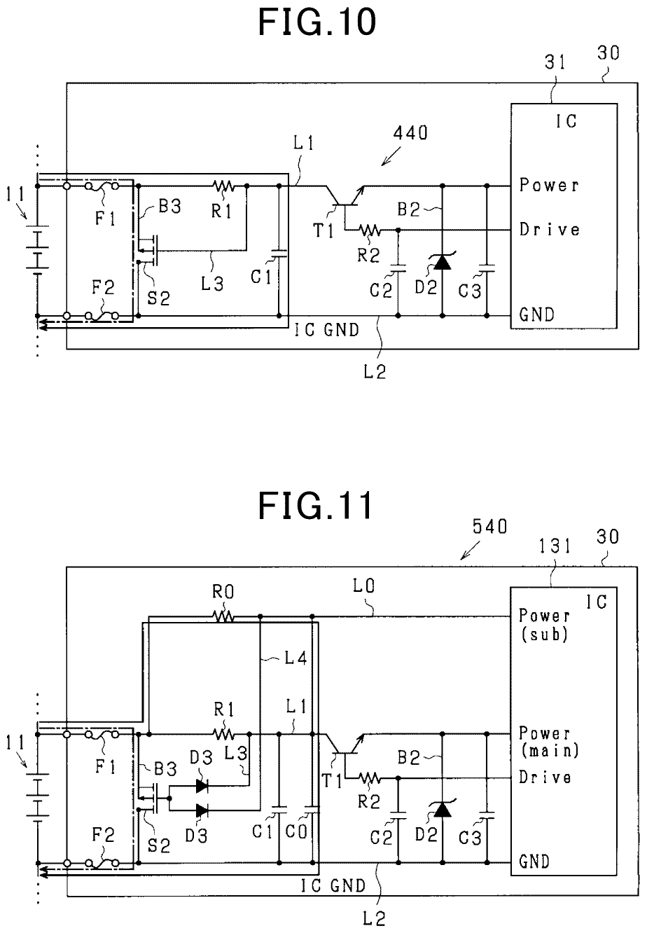

As shown in FIG. 10, the power supply circuit 40 includes a switch S2 connected in parallel with the battery 11 between the fuse F1 and the resistor R1 in the wiring L1. The switch S2 may be, for example, a p-channel MOSFET. The gate of the switch S2 is connected to the connection point of the resistor R1, the transistor T1 and the capacitor C1 by a wiring L3, the source of the switch S2 is connected to the connection point of the fuse F1 and the resistor R1, and the drain of the switch S2 is connected to the connection point of the fuse F2 and the capacitor C1 and GND terminal of the battery monitoring IC. The switch S2 is turned on (closed) when the voltage at the connection point of the wiring L1 and the wiring L3 falls below a threshold value. The threshold value is set to a voltage higher than the voltage applied to the connection point of the wiring L1 and the wiring L3 when the capacitor C1 is short circuited and the predetermined current If that causes the fuse F1 to blow flows through the resistor R1. In other words, the switch S2 is closed when a current exceeding the first current I1, which is less than the predetermined current If, flows through the resistor R1. The first current I1 is smaller than the current flowing through the resistor R1 when the capacitor C1 is short circuited, when the voltage of the battery 11 is the lowest voltage in the range of use (range of variation) or when the resistance value of the resistor R1 is high. The current I1 is smaller than the first current I1 when the capacitor C1 is not short circuited. The wiring L3 constitutes the switch drive unit. The switch S2, the wiring B3, and the wiring L3 constitute the formation circuit.

According to the above configuration, when the capacitor C1 is short circuited and a current exceeding the first current I1 flows through the resistor R1, the switch S2 connected in parallel with the battery 11 between the fuse F1 in the wiring L1 and the resistor R1 closes to form a bypass path, allowing a current exceeding the predetermined current If to flow through the fuse F1 and the fuse F2. Therefore, the discharge current from the battery 11 is interrupted when a short circuit occurs.

When the transistor T1 is short circuited, the Zener diode D2 (second conduction element) energizes. This causes a current exceeding the first current I1 to flow in the resistor R1 and to close the switch S2, and forms a bypass path through the fuse F1, the switch S2, and the fuse F2, in this order. Therefore, a current exceeding the predetermined current If can flow through the fuse F1 and the fuse F2, and the discharge current from the battery 11 is interrupted when transistor T1 is short circuited.

### Seventh Embodiment

The following is a description of the seventh embodiment with reference to the drawings, focusing on the differences from the sixth embodiment. The same parts as those of the sixth embodiment will be omitted from the explanation by applying the same symbols.

As shown in FIG. 11, a power supply circuit 540 includes the wiring L1 (current path) connecting the positive terminal of the battery 11 and the main power input (power (main)) of the battery monitoring IC 31 and the wiring L0 (current path) connecting the positive terminal of battery 11 and the sub power input (power (sub)) of the battery monitoring IC 31.

The resistor R0 (path resistor) is provided in the wiring L0. In the wiring L0, between resistor R0 and the sub power input of the battery monitoring IC, the capacitor C0 is connected in parallel with the battery 11 and the battery monitoring IC 31. The gate of the switch S2 is connected by the wiring L3 to the connection point of the resistor R1 and the transistor T1 and the capacitor C1 via a diode d3. The anode of the diode d3 is connected to the gate of the switch S2, and the cathode is connected to the connection point of the resistor R1, the transistor T1 and the capacitor C1. The gate of the switch S2 is connected to the connection point of the resistor R0, the capacitor C0 and the sub power input (power (sub)) of the battery monitoring IC through the diode d3 by a wiring L4. The anode of the diode d3 is connected to the gate of the switch S2, and the cathode is connected to the connection point of the resistor R0, the capacitor C0 and the sub power input (power (sub)) of the battery monitoring IC. In other words, this embodiment includes the wiring L3 and L4 and the diode d3 (switch drive unit) for wiring L1 and L0 (multiple wiring), respectively, as the formation circuit.

According to the above configuration, even if a short circuit occurs in any of the wires L1 and L0, the discharge current from the battery 11 is interrupted, similar to the sixth embodiment. For example, when the capacitor C0 is short circuited, the switch S2 closes. As a result, the current bypasses the resistors R1 and R0 and flows to the fuse F1, the switch S2, and the fuse F2, in this order. As a result, at least one of the fuse F1 and the fuse F2 blows and the current is interrupted.

### Eighth Embodiment

The following is a description of the eighth embodiment with reference to the drawings, focusing on the differences from the fifth embodiment. The same parts as those of the fifth embodiment will be omitted from the explanation by applying the same symbols.

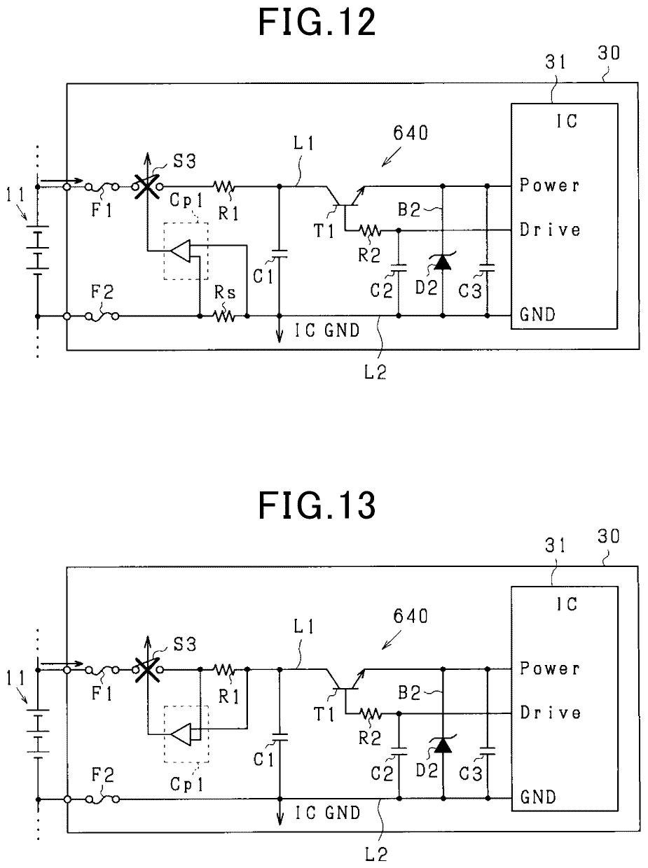

As shown in FIG. 12, a power supply circuit 640 includes a switch S3 connected in series with the fuse F1 and the resistor R1 between the connection point of resistor the R1 (path resistor), the capacitor C1 and the transistor T1 and the battery 11 in the wiring L1. The power supply circuit 640 further includes a comparator Cp1 that drives the switch S3. The switch S3 is a normally closed switch and closes when the output signal from comparator Cp1 is off and opens when it is on. The comparator Cp1 opens the switch S3 when a voltage between ends of the shunt resistor Rs exceeds a threshold value. The threshold value is set to a voltage lower than the voltage applied to the shunt resistor Rs when the capacitor C1 is short circuited and the predetermined current If that causes the fuse F1 to blow flows through the shunt resistor Rs. The comparator Cp1 opens the switch S3 when a current exceeding the first current I1, which is smaller than the predetermined current If, flows through resistor R1. The first current I1 is smaller than the current flowing through the resistor R1 when the capacitor C1 is short circuited, when the voltage of the battery 11 is the lowest voltage in the range of use (range of variation) or when the resistance value of the resistor R1 is high. In other words, comparator Cp1 opens the switch S3 to cut off the current flowing through the resistor R1 when a short circuit occurs in the path through the resistor R1. The comparator Cp1 and the shunt resistor Rs constitute the switch drive unit, and the switch S3, the comparator Cp1, and the shunt resistor Rs constitute the shutdown circuit. An operational amplifier can also be provided instead of the comparator Cp1.

According to the above configuration, the current flowing to the resistor R1 is interrupted even when the current flowing to the fuse F1 and the fuse F2 through the resistor R1 does not exceed the predetermined current If during a short circuit of the capacitor C1. Specifically, when the capacitor C1 is short circuited and a current exceeding the first current I1 flows through the resistor R1, the switch S3 connected in series with the fuse F1 and the resistor R1 in the wiring L1 opens. Therefore, even if a voltage of the battery 11, which is an input source, is low or the resistance value of the resistor R1 is high, the discharge current from the battery 11 is interrupted when a short circuit occurs.

As shown in FIG. 13, the comparator Cp1 may open the switch S1 when a voltage on both ends of the resistor R1 exceeds a threshold value. The threshold value is set to a voltage lower than the voltage applied to the resistor R1 when the capacitor C1 is short circuited and the predetermined current If flows through the resistor R1 that causes the fuse F1 to blow. In other words, the comparator Cp1 opens the switch S3 to cut off the current flowing through the resistor R1 when a short circuit occurs in the path through the resistor R1. The comparator Cp1 and the resistor R1 constitute the switch drive unit, and the switch S3, the comparator Cp1, and the resistor R1 constitute the shutdown circuit. An operational amplifier can also be provided instead of the comparator Cp1.

### Ninth Embodiment

The following is a description of the ninth embodiment with reference to the drawings, focusing on the differences from the first embodiment. The same parts as those of the first embodiment will be omitted from the explanation by applying the same symbols.

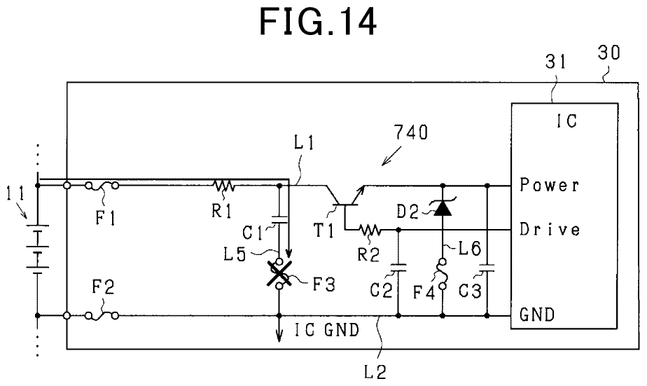

As shown in FIG. 14, the power supply circuit 40 includes a fuse F3 in a wiring L5 that connects the capacitor C1 (predetermined element) to the wiring L1 and the wiring L2. In other words, the fuse F3 (second fuse function unit, interruption circuit) is connected in series with the capacitor C1, which is connected in parallel to the wiring L1. The fuse F3 is connected in series with the capacitor C1, which is assumed to be short circuited. The fuse F3 blows and interrupts the current when a current exceeding the first current I1, which is smaller than the predetermined current If that causes the fuse F1 and the F2 (first fuse function unit) to blow. In detail, the first current I1 is a current smaller than the current that flows through the resistor R1 when a voltage of the battery 11 is the lowest voltage in the range of use (range of variation) or when the resistance value of the resistor R1 is high and the capacitor C1 is short circuited. No current flows through the fuse F3 that exceeds the first current I1, which is smaller than the predetermined current If when a short circuit does not occur in the capacitor C1 (when capacitor C1 is normal).

According to the above configuration, when a short circuit does not occur in the capacitor C1, the fuse F3 does not interrupt the current and allows current to flow in the capacitor C1. On the other hand, the fuse F3 interrupts the current when a current exceeds the first current I1. Therefore, when a short circuit occurs in the capacitor C1, even if the current flowing to the fuse F1 and the fuse F2 does not exceed the predetermined current If and the fuse F1 and the fuse F2 do not work, the current exceeding the first current I1, which is smaller than the predetermined current If, flows to the fuse F3 and the current is interrupted by the fuse F3. Therefore, even if the voltage of the battery 11, which is an input source, is low or the resistance value of the resistor R1 is high, the discharge current from the battery 11 is interrupted when the capacitor C1 is short circuited.

The power supply circuit 40 includes a fuse F4 similar to the fuse F3 in the wiring L6 that connects the Zener diode D2 (predetermined element) to the wiring L1 and L2. In other words, the fuse F4 (second fuse function unit, interruption circuit) is connected in series with the Zener diode D2, which is connected in parallel to the wiring L1. The fuse F3 is connected in series with the Zener diode D2, which is assumed to be short circuited. The fuse F4 blows and interrupts the current when a current exceeding the first current I1, which is smaller than the predetermined current If that causes the fuse F1 and the fuse F2 (first fuse function unit) to blow. When a short circuit does not occur in the Zener diode D2 (when the Zener diode D2 is in a normal state), a current exceeding the first current I1, which is smaller than the predetermined current If, does not flow through the fuse F4. According to this configuration, when a short circuit occurs in the Zener diode D2, even if a current flowing to the fuse F1 and the fuse F2 does not exceed the predetermined current If and the fuse F1 and the fuse F2 do not work, a current exceeding the first current I1 that is smaller than the predetermined current If flows to the fuse F4 and the current is interrupted by the fuse F4.

In the configuration shown in FIG. 14, the switch S3, the comparator Cp1, and the shunt resistor Rs shown in FIG. 12 or the switch S3 and the comparator Cp1 shown in FIG. 13 may be provided.

The first to ninth embodiments and their modifications may also be implemented with the following changes.

The Zener diode D1 (conduction elements) that energizes when voltages exceeding the first predetermined voltages V1 (predetermined voltage) is applied is not limited to a Zener diode, but can also be TVS diodes, varistors, etc. The Zener diode D2 (conduction elements) that energizes when voltages exceeding the second predetermined voltages V2 (predetermined voltage) is applied is not limited to a Zener diode, but can also be TVS diodes, varistors, etc.

The fuse F1 and the fuse F2 are not limited to provided inside the power supply circuit, but may be provided in FPC (boards), the batteries 11, etc. outside the power supply circuit.

Each of the fuse F1 and the fuse F2 (first function unit), and the fuse F3 and the fuse F4 (second fuse function unit) may be resettable fuse whose resistance value increases with overcurrent, e-fuse (electronic fuses) that detect overcurrent and interrupt the current using a MOSFET. In these cases, the fuses F1 to F4 can interrupt (effectively cut off) the current when a current exceeding the predetermined current If flows.

The battery monitoring device 10 is not limited to a configuration in which the main device 20 and the sub device 30 are separated but may be an integrated configuration with the functions of the main device 20 and the sub device 30.

The battery monitoring device 10 may be mounted on an electric flying vehicle such as a drone or electric airplane, or it may be attached to a stationary storage battery.

Each of the above embodiments and their modifications may be combined and implemented to the extent possible.

The following is a description of the characteristic configurations extracted from each of the above-mentioned embodiments and modifications.

### [Configuration 1]

A power supply circuit (40, 140, 240, 340, 440, 540) receiving power from a battery (11) and supplying power to a battery monitoring unit (31) that monitors the condition of the battery, the power supply circuit including:
a fuse function unit (F1, F2), provided in a current path (L1, L2) connecting the battery and the battery monitoring unit, that interrupts a current exceeding a predetermined current;
a path resistor (R1, R0) provided in the current path between the fuse function unit and the battery monitoring unit; and
a formation circuit (D1, B1, D2, B2, D0, B0, S1, S2, B3, Cp1, Rs, R1, L3, L4, D3) that forms a bypass path that allows the current exceeding the predetermined current to flow to the fuse function unit without passing through the path resistor when a short circuit occurs in a path through the path resistor.

### [Configuration 2]

The power supply circuit according to configuration 1, wherein
the formation circuit includes a first conduction element (D1, D0), and
the first conduction element is connected to the current path in parallel with the path resistor, and when a voltage exceeding a first predetermined voltage is applied, energizes and causes a current exceeding the predetermined current to flow to the fuse function unit.

### [Configuration 3]

The power supply circuit according to configuration 2, further including
a switching element (T1) whose open/close state is controlled by the battery monitoring unit, connected in the current path between the path resistor and the first conduction element, and the battery monitoring unit,
wherein the formation circuit includes a second conduction element (D2), and
the second conduction element is connected in parallel with the battery monitoring unit between the switching element and the battery monitoring unit and energizes when a voltage exceeding a second predetermined voltage, which is lower than the first predetermined voltage, is applied.

### [Configuration 4]

The power supply circuit according to configuration 2, wherein
the battery monitoring unit includes a switching element (T1) whose open/close state is controlled by the battery monitoring unit, and
the switching element is provided in the current path (L1).

### [Configuration 5]

The power supply circuit according to any one of configurations 2 to 4 including a plurality of the current paths (L1, L0), wherein
a plurality of the path resistors (R1, R0) is provided in the plurality of the current paths respectively, and
the formation circuit includes a plurality of the first conduction elements (D1, D0) provided in the plurality of the current paths respectively.

### [Configuration 6]

The power supply circuit according to any one of configurations 2 to 5, wherein
the formation circuit includes a noise reduction element (Rf) that reduces noise applied to the first conduction element and has a lower resistance value than the path resistor.

Although this disclosure has been described in accordance with examples, it is understood that this disclosure is not limited to said examples or structures, the present disclosure also encompasses various variations and transformations within the scope of equality, in addition, various combinations and forms, as well as other combinations and forms including only one element, more or less, thereof, also fall within the scope and idea of this disclosure.

What is claimed is:

1. A power supply circuit receiving power from a battery and supplying power to a battery monitoring unit that monitors the condition of the battery, the power supply circuit comprising:
a fuse function unit, provided in a current path connecting the battery and the battery monitoring unit, that interrupts a current exceeding a predetermined current;
a path resistor provided in the current path between the fuse function unit and the battery monitoring unit; and
a formation circuit that forms a bypass path that allows the current exceeding the predetermined current to flow to the fuse function unit without passing through the path resistor when a short circuit occurs in a path through the path resistor.

2. The power supply circuit according to claim 1, wherein
the formation circuit comprises a first conduction element, and
the first conduction element is connected to the current path in parallel with the path resistor, and when a voltage exceeding a first predetermined voltage is applied, energizes and causes a current exceeding the predetermined current to flow to the fuse function unit.

3. The power supply circuit according to claim 2, further comprising
a switching element whose open/close state is controlled by the battery monitoring unit, connected in the current path between the path resistor and the first conduction element, and the battery monitoring unit,
wherein the formation circuit comprises a second conduction element, and
the second conduction element is connected in parallel with the battery monitoring unit between the switching element and the battery monitoring unit and energizes when a voltage exceeding a second predetermined voltage, which is lower than the first predetermined voltage, is applied.

4. The power supply circuit according to claim 2, wherein
the battery monitoring unit comprises a switching element whose open/close state is controlled by the battery monitoring unit, and
the switching element is provided in the current path.

5. The power supply circuit according to claim 2 comprising a plurality of the current paths, wherein
a plurality of the path resistors is provided in the plurality of the current paths respectively, and
the formation circuit comprises a plurality of the first conduction elements provided in the plurality of the current paths respectively.

6. The power supply circuit according to claim 2, wherein
the formation circuit comprises a noise reduction element that reduces noise applied to the first conduction element and has a lower resistance value than the path resistor.

7. The power supply circuit according to claim 1, wherein
the formation circuit comprises:
a switch connected in parallel with the battery in the current path between the fuse function unit and the path resistor; and
a switch drive unit that closes the switch when a current exceeding the first current, which is smaller than the predetermined current, flows through the path resistor.

8. The power supply circuit according to claim 7, further comprising
a switching element whose open/close state is controlled by the battery monitoring unit is connected in the current path between the path resistor and the battery monitoring unit, wherein
the formation circuit comprises a second conduction element, and
the second conduction element is connected in parallel with the battery monitoring unit in the current path between the switching element and the battery monitoring unit and energizes when a voltage exceeding the second predetermined voltage is applied.

9. The power supply circuit according to claim 7 comprising a plurality of the current paths, wherein
a plurality of the path resistors is provided in the plurality of the current paths respectively, and
the formation circuit comprises a plurality of the switch drive units provided in the plurality of the current paths respectively.

10. A power supply circuit receiving power from a battery and supplying power to a battery monitoring unit that monitors the condition of the battery, the power supply circuit comprising:
a first fuse function unit, provided in a current path connecting the battery and the battery monitoring unit, that interrupts a current exceeding a predetermined current;
a path resistor provided in the current path between the first fuse function unit and the battery monitoring unit; and
an interruption circuit that interrupts the current flowing through the path resistor when a short circuit occurs in the path through the path resistor,
wherein
the interruption circuit comprises:
a switch connected in series with the first fuse function unit and the path resistor in the current path; and
a switch drive unit that opens the switch when a current exceeding the first current, which is smaller than the predetermined current, flows through the path resistor.

11. The power supply circuit according to claim 10, wherein
the interruption circuit comprises a second fuse function unit,
the second fuse function unit is connected in series with a predetermined element, the predetermined element being connected in parallel with the current path, and
when a short circuit does not occur in the predetermined element a current exceeding a first current that is smaller than the predetermined current does not flow, and a current exceeding the first current flows, the second fuse function unit interrupts the current flowing through the path resistor.

12. A power supply circuit receiving power from a battery and supplying power to a battery monitoring unit that monitors the condition of the battery, the power supply circuit comprising:
a first fuse function unit, provided in a current path connecting the battery and the battery monitoring unit, that interrupts a current exceeding a predetermined current;
a path resistor provided in the current path between the first fuse function unit and the battery monitoring unit; and
an interruption circuit that interrupts the current flowing through the path resistor when a short circuit occurs in the path through the path resistor,
wherein
the interruption circuit comprises a second fuse function unit,
the second fuse function unit is connected in series with a predetermined element, the predetermined element being connected in parallel with the current path, and
when a short circuit does not occur in the predetermined element a current exceeding a first current that is smaller than the predetermined current does not flow, and a current exceeding the first current flows, the second fuse function unit interrupts the current flowing through the path resistor.
